(19) United States
(12) Patent Application Publication
(10) Pub. No.: US 2023/0297733 A1
(43) Pub. Date: Sep. 21, 2023

(54) METHOD AND SYSTEM FOR AUTOMATICALLY IDENTIFYING TUBE ELEMENTS

(71) Applicant: HCL Technologies Limited, New Delhi (IN)

(72) Inventors: GIRISH RAMESH CHANDANKAR, Mumbai (IN); HARI KRISHNAN ELUMALAI, Chennai (IN); PANKAJ GUPTA, Mumbai (IN); RAJESH CHAKRAVARTY, Mumbai (IN); AKASH AGRAWAL, Pune (IN); PANKAJ PANDA, Mumbai (IN)

(21) Appl. No.: 17/747,017

(22) Filed: May 18, 2022

(30) Foreign Application Priority Data
Mar. 16, 2022 (IN) 202211014194

(51) Int. Cl. G06F 30/17; G06F 30/20

(52) U.S. Cl. CPC G06F 30/17; G06F 30/20

(57) ABSTRACT

The invention relates to method and system for automatically identifying tube elements in a Boundary Representation (B-Rep)-based Computer Aided Design (CAD) model of a tube. The method includes extracting information corresponding to the B-Rep-based CAD model of the tube; validating geometrical features of the B-Rep based CAD model of the tube based on the extracted information; classifying each of a plurality of faces of the tube into one of a set of face types; determining one or more regions on the tube using a set of connected top faces of the tube; generating a plurality of primary tube elements and a set of secondary tube elements based on shapes of the plurality of regions; determining a plurality of element parameters for each of the plurality of tube elements of the tube; and determining a plurality of tube parameters for the tube based on the plurality of element parameters.

### TECHNICAL FIELD

Generally, the invention relates to Boundary Representation (B-Rep) models. More specifically, the invention relates to a method and system for automatically identifying tube elements.

### BACKGROUND

Typically, a Boundary representation (B-Rep) model of a mechanical part (for example, a tube) includes faces, edges, and vertices. The faces, the edges, and the vertices may be connected to form a topological structure of the mechanical part. Information of the B-Rep model of the mechanical part may be stored in a graph structure. In the graph structure, each node represents a face and each link/connection represents an edge. This type of representation helps in evaluating properties of the mechanical part. The properties may include mass, volume, moment of inertia, and the like. Additionally, such B-Rep models enable computer-based analysis of stress and strains in the mechanical part under different loading conditions. Further, a B-rep based computer model may also be cut and examined in a manner like an actual part. Therefore, the B-rep model of the mechanical part is known as a Solid model.

Further, a tube is a hollow or a solid object created by sweeping a cross section profile along a path. The cross-section profile is usually constant resulting into a tube with constant thickness. The commonly occurring cross-section profile is circular, and the path of sweeping is straight, resulting in cylindrical tubes.

Today, various software based on solid modeling are widely used by engineers to create models of the mechanical parts that are intended to eventually be manufactured. Examples of the software may include SOLIDWorks and Catia (Dassault Systems), Creo Parametric (PTC), and the like. Additionally, various B-rep based Computer Aided Design (CAD) models are available in neutral formats (like IGES and STEP). However, in these models, tube feature and associated parameter information is unavailable. Therefore, there is a need to develop a method and system that may automatically identify tube elements.

### SUMMARY

In one embodiment, a method for automatically identifying tube elements in a Boundary Representation (B-Rep)-based Computer Aided Design (CAD) model of a tube is disclosed. The method may include extracting information corresponding to the B-Rep-based CAD model of the tube. The method may further include validating geometrical features of the B-Rep based CAD model of the tube based on the extracted information. The method may further include classifying each of a plurality of faces of the tube into one of a set of face types. The set of face types may include a top face, a bottom face, or a lateral face. The top face may be located on outer surface of the tube, the bottom face may be located on inner surface of the tube, and the lateral face may be located on cross-section of the tube. The method may further include determining one or more regions on the tube using a set of connected top faces of the tube. It should be noted that each of the one or more regions may be a section of the tube with a consistent sweep path, and each of the one or more regions may be one of a length region, a bend region, or a spline region The method may further include generating a plurality of primary tube elements based on shapes of the plurality of regions. It should be noted that each of the plurality of primary tube elements may be one of a bend element, a length element, or a spline element.

In another embodiment, a system for automatically identifying tube elements in a Boundary Representation (B-Rep)-based Computer Aided Design (CAD) model of a tube is disclosed. The system may include a processor and a memory communicatively coupled to the processor. The memory may store processor-executable instructions, which, on execution, may cause the processor to extract information corresponding to the B-Rep-based CAD model of the tube. The processor-executable instructions, on execution, may further cause the processor to validate geometrical features of the B-Rep based CAD model of the tube based on the extracted information. The processor-executable instructions, on execution, may further cause the processor to classify each of a plurality of faces of the tube into one of a set of face types. The set of face types may include a top face, a bottom face, or a lateral face. The top face may be located on outer surface of the tube, the bottom face may be located on inner surface of the tube, and the lateral face may be located on cross-section of the tube. The processor-executable instructions, on execution, may further cause the processor to determine one or more regions on the tube using a set of connected top faces of the tube. It should be noted that each of the one or more regions may be a section of the tube with a consistent sweep path, and each of the one or more regions may be one of a length region, a bend region, or a spline region. The processor-executable instructions, on execution, may further cause the processor to generate a plurality of primary tube elements based on shapes of the plurality of regions. It should be noted that each of the plurality of primary tube elements may be one of a bend element, a length element, or a spline element.

In yet another embodiment, a non-transitory computer-readable medium storing computer-executable instruction for automatically identifying tube elements in a Boundary Representation (B-Rep)-based Computer Aided Design (CAD) model of a tube is disclosed. The stored instructions, when executed by a processor, may cause the processor to perform operations including extracting information corresponding to the B-Rep-based CAD model of the tube. The operations may further include validating geometrical features of the B-Rep based CAD model of the tube based on the extracted information. The operations may further include classifying each of a plurality of faces of the tube into one of a set of face types. The set of face types may include a top face, a bottom face, or a lateral face. The top face may be located on outer surface of the tube, the bottom face may be located on inner surface of the tube, and the lateral face may be located on cross-section of the tube. The operations may further include determining one or more regions on the tube using a set of connected top faces of the tube. It should be noted that each of the one or more regions may be a section of the tube with a consistent sweep path, and each of the one or more regions may be one of a length region, a bend region, or a spline region. The operations may further include generating a plurality of primary tube elements based on shapes of the plurality of regions. It should be noted that each of the plurality of primary tube elements may be one of a bend element, a length element, or a spline element.

It is to be understood that both the foregoing general description and the following detailed description are exemplary and explanatory only and are not restrictive of the invention, as claimed.

### BRIEF DESCRIPTION OF THE DRAWINGS

The present application can be best understood by reference to the following description taken in conjunction with the accompanying drawing figures, in which like parts may be referred to by like numerals

FIG. 1 illustrates an element recognition device configured for automatically identifying tube elements in a Boundary Representation (B-Rep)-based Computer Aided Design (CAD) model of a tube, in accordance with some embodiments of the present disclosure.

FIG. 2 illustrates a flow diagram of an exemplary process for automatically identifying tube elements in a Boundary Representation (B-Rep)-based Computer Aided Design (CAD) model of a tube, in accordance with some embodiments of the present disclosure.

FIGS. 3A-E illustrate various tube elements generated by an element recognition device, in accordance with some embodiments of the present disclosure.

FIGS. 4A-C illustrate validation of geometrical features of an exemplary B-Rep based CAD model of a tube, in accordance with some embodiments of the present disclosure.

FIGS. 5A-D illustrate a plurality of face types for an exemplary tube, in accordance with some embodiments of the present disclosure.

FIG. 6 illustrates a length region on an exemplary tube, in accordance with some embodiments of the present disclosure.

FIGS. 7A-B illustrate exemplary cross-section profiles of an exemplary tube and sections of reporting the cross-section profiles respectively, in accordance with some embodiments of the present disclosure.

FIG. 8 is a block diagram of an exemplary computer system for implementing embodiments consistent with the present disclosure.

### DETAILED DESCRIPTION OF THE DRAWINGS

The following description is presented to enable a person of ordinary skill in the art to make and use the invention and is provided in the context of particular applications and their requirements. Various modifications to the embodiments will be readily apparent to those skilled in the art, and the generic principles defined herein may be applied to other embodiments and applications without departing from the spirit and scope of the invention. Moreover, in the following description, numerous details are set forth for the purpose of explanation. However, one of ordinary skill in the art will realize that the invention might be practiced without the use of these specific details. In other instances, well-known structures and devices are shown in block diagram form in order not to obscure the description of the invention with unnecessary detail. Thus, the present invention is not intended to be limited to the embodiments shown, but is to be accorded the widest scope consistent with the principles and features disclosed herein.

While the invention is described in terms of particular examples and illustrative figures, those of ordinary skill in the art will recognize that the invention is not limited to the examples or figures described. Those skilled in the art will recognize that the operations of the various embodiments may be implemented using hardware, software, firmware, or combinations thereof, as appropriate. For example, some processes can be carried out using processors or other digital circuitry under the control of software, firmware, or hard-wired logic. (The term “logic” herein refers to fixed hardware, programmable logic and/or an appropriate combination thereof, as would be recognized by one skilled in the art to carry out the recited functions). Software and firmware can be stored on computer-readable storage media. Some other processes can be implemented using analog circuitry, as is well known to one of ordinary skill in the art. Additionally, memory or other storage, as well as communication components, may be employed in embodiments of the invention.

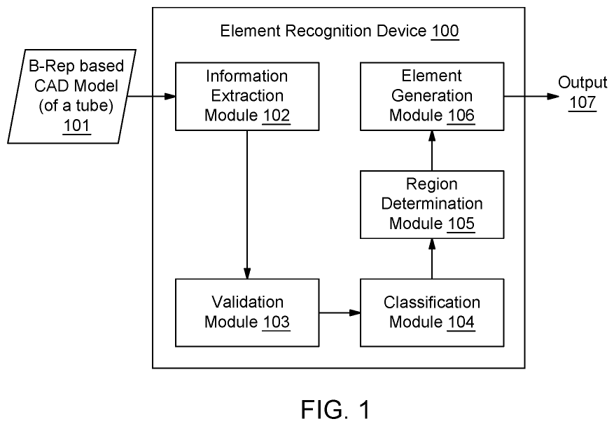

Referring now to FIG. 1, an element recognition device 100 configured for automatically identifying tube elements in a Boundary Representation (B-Rep)-based Computer Aided Design (CAD) model of a tube is illustrated, in accordance with some embodiments of the present disclosure. In some embodiments, the element recognition device 100 may include an information extraction module 102, a validation module 103, a classification module 104, a region determination module 105, and an element generation module 106. Further, the element recognition device 100 may also include a data store (not shown in FIG. 1) in order to store intermediate results generated by the modules 102-106.

The information extraction module 102 may be configured to extract information corresponding to the B-Rep-based CAD model of the tube. In some embodiments, the extracted information may be further used to identify the plurality of faces from the B-Rep based CAD model of the tube. The information extraction module 102 may be communicatively coupled to the validation module 103.

The validation module 103 may be configured to validate geometrical features of the B-Rep based CAD model of the tube. It should be noted that validation may be performed based on the information extracted by the information extraction module 102. In some embodiments, a tube type may be determined for the tube corresponding to the B-Rep based CAD model based on the extracted information. The tube type may be one of a hollow type, a solid type, or a mixed type. To determine the tube type, in some embodiments, one or more clue faces may be identified from the plurality of faces in the B-Rep-based CAD model. The one or more clue faces of the B-Rep-based CAD model may be analyzed to determine the tube type. In some embodiments, thickness of the tube may be determined based on the tube type using the extracted information. In some other embodiments, uniformity of the determined thickness of the tube may be validated. Further, the validation module 103 may be operatively coupled to the classification module 104 and transmit data upon successful validation of the geometrical features of the B-Rep based CAD model

The classification module 104 may be configured to classify each of a plurality of faces of the tube into one of a set of face types. It should be noted that the set of face types may include a top face, a bottom face, or a lateral face. Further, the top face may be located on outer surface of the tube. The bottom face may be located on inner surface of the tube. The lateral face may be located on cross-section of the tube. The classification module 104 may transmit the set of face types in the B-Rep based CAD model as an output to the connected region determination module 105.

The region determination module 105 may be configured to determine one or more regions on the tube. The region determination module 105 may use a set of connected top faces of the tube for performing its function. It should be noted that each of the one or more regions may be a section of the tube with a consistent sweep path. Further each of the one or more regions may be one of a length region, a bend region, or a spline region. Further, the region determination module 105 may be communicatively coupled to the element generation module 106.

The element generation module 106 may be configured to generate a plurality of primary tube elements. Further, shapes of the plurality of regions may be utilized to generate the plurality of tube elements. It should be noted that each of the plurality of primary tube elements is one of a bend element, a length element, or a spline element. In some embodiments, the element generation module 106 may be configured for generating a set of secondary tube elements based on the plurality of primary tube elements. The plurality of primary tube elements and the set of secondary tube elements comprise a length element, a bend element, a spline element, and a collar element.

Further, in some embodiments a sweep path of the tube may be calculated to validate consistency of circular cross-section of the tube. Additionally, in some embodiments, a plurality of element parameters may be determined for each of the plurality of tube elements of the tube. Further, a plurality of tube parameters for the tube may be determined based on the plurality of element parameters.

It should be noted that the element recognition device 100 may be implemented in programmable hardware devices such as programmable gate arrays, programmable array logic, programmable logic devices, or the like. Alternatively, the element recognition device 100 may be implemented in software for execution by various types of processors. An identified engine/module of executable code may, for instance, include one or more physical or logical blocks of computer instructions which may, for instance, be organized as a component, module, procedure, function, or other construct. Nevertheless, the executables of an identified engine/module need not be physically located together but may include disparate instructions stored in different locations which, when joined logically together, comprise the identified engine/module and achieve the stated purpose of the identified engine/module. Indeed, an engine or a module of executable code may be a single instruction, or many instructions, and may even be distributed over several different code segments, among different applications, and across several memory devices.

As will be appreciated by one skilled in the art, a variety of processes may be employed for automatic data security and loss protection. For example, the exemplary element recognition device 100 may automatically identify tube elements in a Boundary Representation (B-Rep), by the process discussed herein. In particular, as will be appreciated by those of ordinary skill in the art, control logic and/or automated routines for performing the techniques and steps described herein may be implemented by the element recognition device 100 either by hardware, software, or combinations of hardware and software. For example, suitable code may be accessed and executed by the one or more processors on the element recognition device 100 to perform some or all of the techniques described herein. Similarly, application specific integrated circuits (ASICs) configured to perform some or all the processes described herein may be included in the one or more processors of the element recognition device 100.

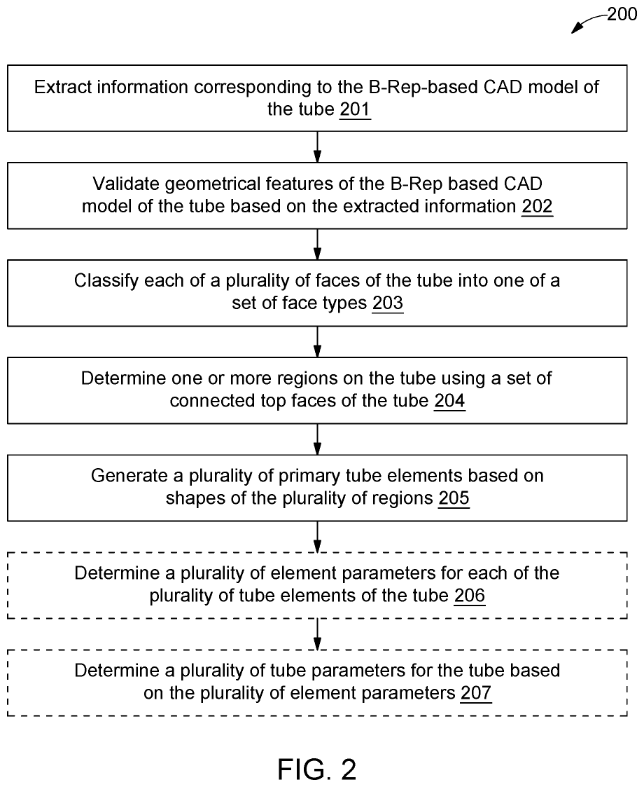

Referring now to FIG. 2, an exemplary process 200 for automatically identifying tube elements in a Boundary Representation (B-Rep)-based Computer Aided Design (CAD) model of a tube is depicted via a flow diagram, in accordance with some embodiments of the present disclosure. Each step of the process 200 may be performed by an element recognition device (similar to the element recognition device 100). FIG. 2 is explained in conjunction with FIG. 1.

At step 201, information corresponding to the B-Rep-based CAD model of the tube may be extracted. An information extraction module (same as the information extraction module 103) may be used to perform this step. Further, in some embodiments, a plurality of faces from the B-Rep based CAD model of the tube may be identified.

At step 202, geometrical features of the B-Rep based CAD model of the tube may be validated using a validation module (similar to the validation module 103). It should be noted that validation may be performed based on the extracted information. In some embodiments, a tube type for the tube corresponding to the B-Rep based CAD model may be determined based on the extracted information. It should be noted that the tube type may include one of a hollow type, a solid type, or a mixed type. To identify the tube type, one or more clue faces may be identified from the plurality of faces in the B-Rep-based CAD model. The one or more clue faces of the B-Rep-based CAD model may be analyzed to determine the tube type. Further, in some embodiments, a sweep path of the tube may be calculated to validate consistency of circular cross-section. In some other embodiments, thickness of the tube based on the tube type using the extracted information may be determined. Further, uniformity of the determined thickness of the tube may be validated.

At step 203, each of the plurality of faces of the tube may be classified into one of a set of face types upon successful validation. A classification module (same as the classification module 104) may be used for classifying the each of a plurality of faces. It should be noted that the set of face types may include a top face, a bottom face, or a lateral face. Further, the top face may be located on outer surface of the tube. The bottom face may be located on inner surface of the tube. The lateral face may be located on cross-section of the tube.

Thereafter, at step 204, one or more regions on the tube may be determined. It should be noted that a set of connected top faces of the tube may be considered for region determination. Also, it should be noted that a region determination module (analogous to the region determination module 105) may be used for determining the one or more regions on the tube). Each of the one or more regions may be a section of the tube with a consistent sweep path. And, each of the one or more regions may be one of a length region, a bend region, or a spline region.

At step 205, a plurality of primary tube elements may be generated based on shapes of the plurality of regions. It should be noted that an element generation module (same as the element generation module 106) may be used for performing this step. Further, each of the plurality of primary tube elements may be one of a bend element, a length element, or a spline element.

In some embodiments, a set of secondary tube elements may be generated based on the plurality of primary tube elements. It should be noted that the set of secondary tube elements may include a collar element.

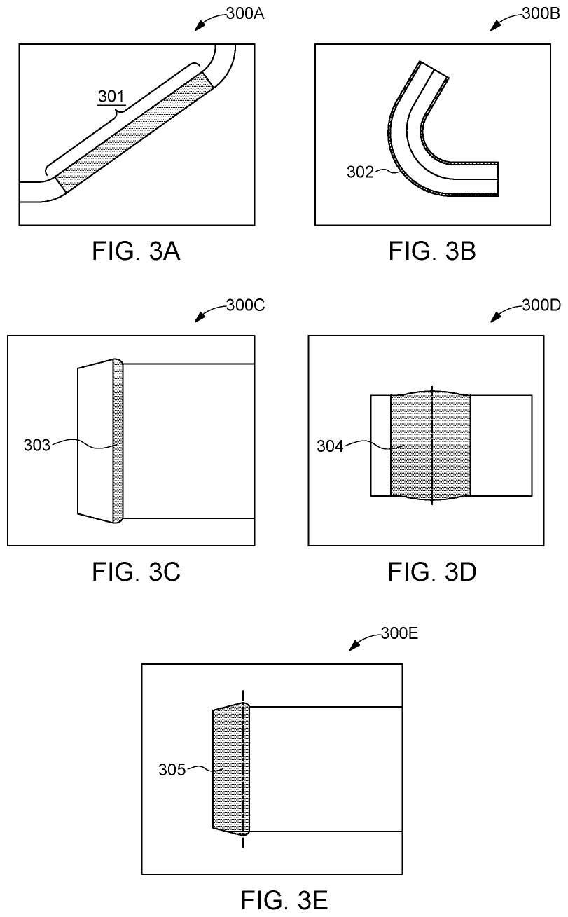

In other words, tube elements (i.e., the primary tube elements and the secondary tube elements) from regions on the tube may be generated based on shape of the region. For example, if a region has a toroidal shape, a bend tube element may be created from the region. In another example, for a region having a conical shape, a length tube element may be created from the region. For a region with any other shape, a spline element may be created. Further based on the primary tube elements, complex tube elements like collar elements may be generated. It should be noted that a collar element may be obtained by aggregating the primary tube elements. In the collar tube element, a bulge region may be in the middle, followed by regions of smooth transitions to the length/bend/spline tube elements on both sides of the bulge. This is explained further in conjunction with FIGS. 3D and 3E.

At step 206, a plurality of element parameters may be determined for each of the plurality of tube elements of the tube. At step 207, based on the plurality of tube element parameters, a plurality of tube parameters may be determined. In other words, once the tube elements are identified from the tube regions, the plurality of element parameters may be determined. The plurality of element parameters may include, but are not limited to, a sweep path, a length of a tube element, and the cross-section of the tube element. A sweep path may be a path that generates the tube element when a cross-section shape of the tube element is swept through such path. After creating the sweep path for each tube element, sweep paths may be combined from end to end to form sweep path for the entire tube. Further, length of the whole tube may be calculated by adding lengths of the sweep paths of constituent tube elements.

Referring now to FIGS. 3A-E, various tube elements 301, 302, 303, 304, and 305 generated by an element recognition device (same as the element recognition device 100) are illustrated, in accordance with some embodiments of the present disclosure. FIGS. 3A-E are illustrated in conjunction with FIGS. 1-2. FIG. 3A illustrates a length tube element 301. The length tube element may be characterized by a linear nature of its axis (for example, sweep path).

Further, FIG. 3B illustrates a bend tube element 302. The bend tube element 302 may be a result from sweeping a constant circular cross-section profile along a circular path. As shown in the FIG. 3B, a tube bend may be recognized as bend tube element along with its parameters. FIG. 3C illustrates a spline tube element 303. The spline tube element 303 may be a result from sweeping a variable circular cross section profile along a path. The sweep path may be linear, circular, or of any other shape. It should be noted that the spline tube element 303 may be of constant thickness along the sweep path. An element that may not fall into length or bend may be considered as a spline tube element.

Further, FIGS. 3D and 3E illustrate collar tube elements 304 and 305, respectively. A collar tube element may be a region along the axis of the tube having a different radius than the length tube element and the bend tube element. The collar tube elements 304 and 305 are characterized by a bulge in the middle portion and smooth transitions to the length tube element and the bend tube element on both sides. Collars may be differentiated from flanges by a type of transition between a region of a collar and the tube. A flange may have a sharp transition between adjacent regions. However, the collar may have smooth transitions. The collar may be of two types based on symmetry. In particular, FIG. 3D illustrate a symmetric collar tube element, i.e., 304. In the symmetric collar tube element 304, features may be symmetrical about a plane perpendicular to an axis and pass through a circular cross-section with maximum radius. FIG. 3E illustrates a non-symmetric collar tube element 305. In the non-symmetric collar tube element 305, features may not be symmetrical about the plane perpendicular to the axis and passing through the circular cross-section with maximum radius.

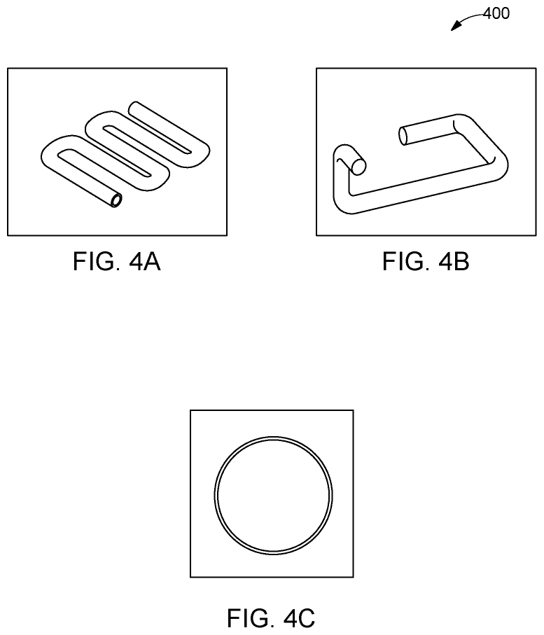

Referring now to FIGS. 4A-C, validation of geometrical features of an exemplary B-Rep based CAD model 400 of a tube is illustrated, in accordance with some embodiments of the present disclosure. FIGS. 4A-C are explained in conjunction with FIGS. 1-3. For validation, a tube type for the B-Rep based CAD model 400 may be identified. For example, the tube type may be one of a hollow type, a solid type, or a mixed type. The hollow tube type is illustrated in FIG. 4A. Further, the solid tube type is illustrated in FIG. 4B. In some embodiments, clue faces in the B-Rep based CAD model 400 may be identified. In some embodiments, consistency of circular cross-section shape of the tube may be checked. The validation may be considered as successful validation if thickness of the tube is constant. Tube thickness is illustrated in FIG. 4C.

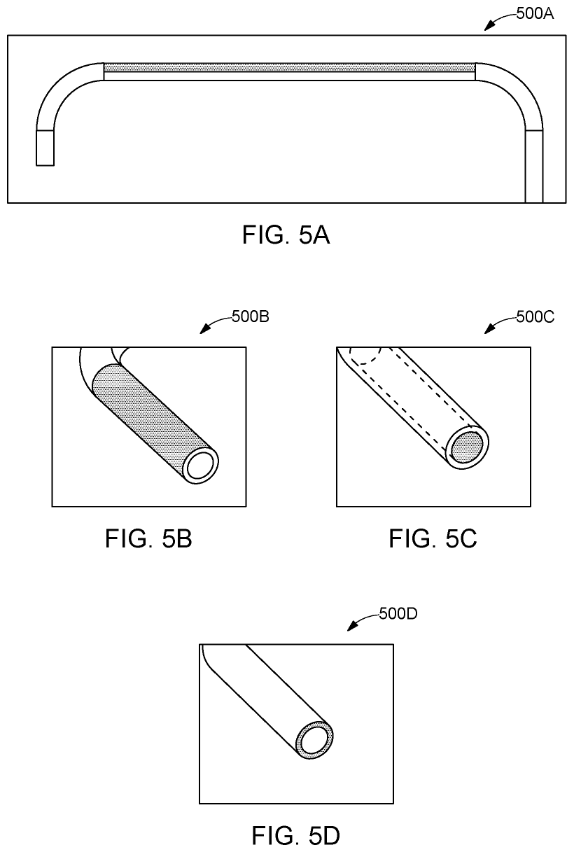

Referring now to FIGS. 5A-D, a plurality of face types for an exemplary tube are illustrated, in accordance with some embodiments of the present disclosure. FIGS. 5A-D are explained in conjunction with FIGS. 1-4. After calculating the thickness, each of faces of the tube may be segregated into one of a top face, a bottom face, and a lateral face based on a reference face. It should be noted that the reference face may correspond to a face with the maximum area. FIG. 5A illustrates a reference face 500A which may be used to segregate faces of the tube. FIG. 5B illustrates a top face 500B, FIG. 5C illustrates a bottom face 500C, and FIG. 5D illustrates a lateral face 500D of the tube. The top face 500B may be collected by propagating through faces connected with the reference face 500A. The bottom face 500C may be an opposite face of collected top faces (For example, the top face 500B). It should be noted that faces which do not fall under top faces and bottom faces may be classified as lateral faces (for example, the lateral face 500D).

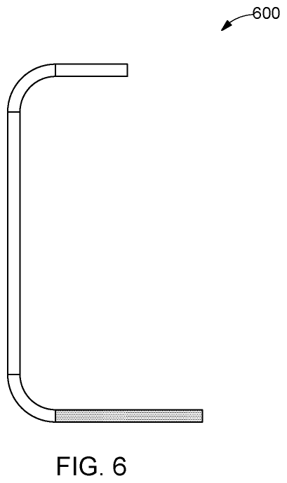

Referring now to FIG. 6, a length region on an exemplary tube is illustrated, in accordance with some embodiments of the present disclosure. FIG. 6 is explained in conjunction with FIGS. 1-5. A region may be a set of connected faces that may be further validated for tube elements. Regions may be determined based on the top faces of the tube. The regions may include, but are not limited to, a length region, a bend, and a spline region. The regions may be determined corresponding to various tube sections within which geometry of sweep path may be unchanged.

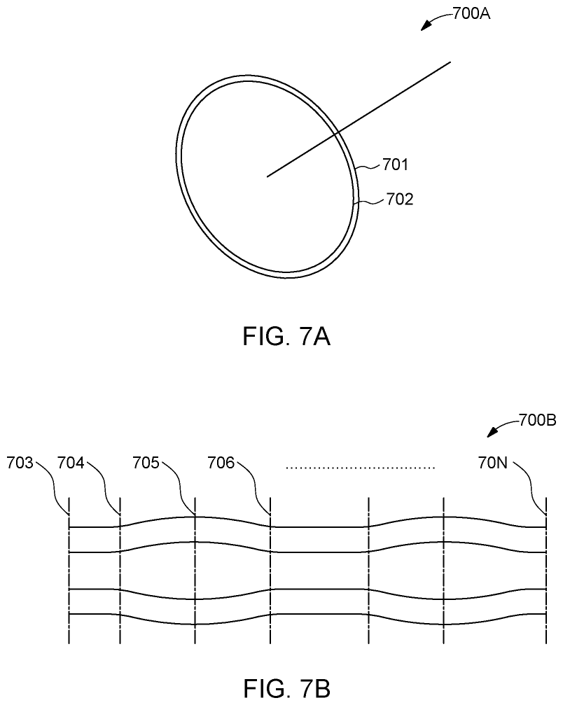

Referring now to FIG. 7A-B, cross-section profiles of an exemplary tube and sections of reporting the cross-section profiles respectively are illustrated, in accordance with some embodiments of the present disclosure. FIGS-7A-B are explained in conjunction with FIGS. 1-6. FIG. 7A illustrate outer cross-section profile 701 and inner cross-section profile 702 of the tube. The element recognition device 100 may determine the outer cross-section profile 701 and the inner cross-section profile 702 at two extreme ends of each tube element and at points of local maxima of the cross-section along the sweep path of the tube.

FIG. 7B illustrates various sections where the cross-section profiles may be reported. For, example the sections 703, 704, 705, 706, and 70N. Here, ‘N’ is nth section where the cross-section profiles may be reported.

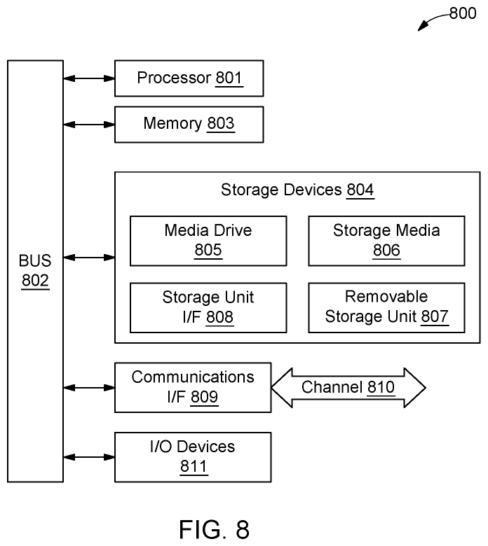

The disclosed methods and systems may be implemented on a conventional or a general-purpose computer system, such as a personal computer (PC) or server computer. Referring now to FIG. 8, an exemplary computing system 800 that may be employed to implement processing functionality for various embodiments (e.g., as a SIMD device, client device, server device, one or more processors, or the like) is illustrated. Those skilled in the relevant art will also recognize how to implement the invention using other computer systems or architectures. The computing system 800 may represent, for example, a user device such as a desktop, a laptop, a mobile phone, personal entertainment device, DVR, and so on, or any other type of special or general-purpose computing device as may be desirable or appropriate for a given application or environment. The computing system 800 may include one or more processors, such as a processor 801 that may be implemented using a general or special purpose processing engine such as, for example, a microprocessor, microcontroller or other control logic. In this example, the processor 801 is connected to a bus 802 or other communication medium. In some embodiments, the processor 801 may be an AI processor, which may be implemented as a Tensor Processing Unit (TPU), or a graphical processor unit, or a custom programmable solution Field-Programmable Gate Array (FPGA).

The computing system 800 may also include a memory 803 (main memory), for example, Random Access Memory (RAM) or other dynamic memory, for storing information and instructions to be executed by the processor 801. The memory 803 also may be used for storing temporary variables or other intermediate information during execution of instructions to be executed by the processor 801. The computing system 800 may likewise include a read only memory (“ROM”) or other static storage device coupled to bus 802 for storing static information and instructions for the processor 801.

The computing system 800 may also include a storage device 804, which may include, for example, a media drives 805 and a removable storage interface. The media drive 805 may include a drive or other mechanism to support fixed or removable storage media, such as a hard disk drive, a floppy disk drive, a magnetic tape drive, an SD card port, a USB port, a micro USB, an optical disk drive, a CD or DVD drive (R or RW), or other removable or fixed media drive. A storage media 806 may include, for example, a hard disk, magnetic tape, flash drive, or other fixed or removable medium that is read by and written to by the media drive 805. As these examples illustrate, the storage media 806 may include a computer-readable storage medium having stored there in particular computer software or data.

In alternative embodiments, the storage devices 804 may include other similar instrumentalities for allowing computer programs or other instructions or data to be loaded into the computing system 800. Such instrumentalities may include, for example, a removable storage unit 807 and a storage unit interface 808, such as a program cartridge and cartridge interface, a removable memory (for example, a flash memory or other removable memory module) and memory slot, and other removable storage units and interfaces that allow software and data to be transferred from the removable storage unit 807 to the computing system 800.

The computing system 800 may also include a communications interface 809. The communications interface 809 may be used to allow software and data to be transferred between the computing system 800 and external devices. Examples of the communications interface 809 may include a network interface (such as an Ethernet or other NIC card), a communications port (such as for example, a USB port, a micro USB port), Near field Communication (NFC), etc. Software and data transferred via the communications interface 809 are in the form of signals which may be electronic, electromagnetic, optical, or other signals capable of being received by the communications interface 809. These signals are provided to the communications interface 809 via a channel 810. The channel 810 may carry signals and may be implemented using a wireless medium, wire or cable, fiber optics, or other communications medium. Some examples of the channel 810 may include a phone line, a cellular phone link, an RF link, a Bluetooth link, a network interface, a local or wide area network, and other communications channels.

The computing system 800 may further include Input/Output (I/O) devices 811. Examples may include, but are not limited to a display, keypad, microphone, audio speakers, vibrating motor, LED lights, etc. The I/O devices 811 may receive input from a user and also display an output of the computation performed by the processor 801. In this document, the terms “computer program product” and “computer-readable medium” may be used generally to refer to media such as, for example, the memory 803, the storage devices 804, the removable storage unit 807, or signal(s) on the channel 810. These and other forms of computer-readable media may be involved in providing one or more sequences of one or more instructions to the processor 801 for execution. Such instructions, generally referred to as “computer program code” (which may be grouped in the form of computer programs or other groupings), when executed, enable the computing system 800 to perform features or functions of embodiments of the present invention.

In an embodiment where the elements are implemented using software, the software may be stored in a computer-readable medium and loaded into the computing system 800 using, for example, the removable storage unit 807, the media drive 805 or the communications interface 809. The control logic (in this example, software instructions or computer program code), when executed by the processor 801, causes the processor 801 to perform the functions of the invention as described herein.

Thus, the present disclosure may overcome drawbacks of traditional systems discussed before. The disclosed method and system in the present disclosure may be useful in various domains like oil and gas industries, automobile industries, aerospace industries, piping industries, and the like. Also, the disclosure helps in determining costs of the materials, finding matching pairs or components, providing an optimized layout, and providing design modifications.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or process steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A method for automatically identifying tube elements in a Boundary Representation (B-Rep)-based Computer Aided Design (CAD) model of a tube, the method comprising:
extracting, by an element recognition device, information corresponding to the B-Rep-based CAD model of the tube;
validating, by the element recognition device, geometrical features of the B-Rep based CAD model of the tube based on the extracted information;
classifying, by the element recognition device, each of a plurality of faces of the tube into one of a set of face types upon successful validation, wherein the set of face types comprises a top face, a bottom face, or a lateral face, wherein the top face is located on outer surface of the tube, the bottom face is located on inner surface of the tube, and the lateral face is located on cross-section of the tube;
determining, by the element recognition device, one or more regions on the tube using a set of connected top faces of the tube, wherein each of the one or more regions is a section of the tube with a consistent sweep path, and wherein each of the one or more regions is one of a length region, a bend region, or a spline region; and
generating, by the element recognition device, a plurality of primary tube elements based on shapes of the plurality of regions, wherein each of the plurality of primary tube elements is one of a bend element, a length element, or a spline element.

2. The method of claim 1, further comprising generating a set of secondary tube elements based on the plurality of primary tube elements.

3. The method of claim 2, wherein the set of secondary tube elements comprise a collar element.

4. The method of claim 1, wherein extracting information further comprises identifying the plurality of faces from the B-Rep based CAD model of the tube.

5. The method of claim 1, wherein validating geometrical features of the B-Rep based CAD model comprises:
determining a tube type for the tube corresponding to the B-Rep based CAD model based on the extracted information, wherein the tube type is one of a hollow type, a solid type, or a mixed type, and wherein determining comprises:
identifying one or more clue faces from the plurality of faces in the B-Rep-based CAD model; and
analysing the one or more clue faces of the B-Rep-based CAD model to determine the tube type.

6. The method of claim 5, further comprising:
calculating a sweep path of the tube; and
validating consistency of circular cross-section of the tube;

7. The method of claim 5, further comprising:
determining thickness of the tube based on the tube type using the extracted information; and
validating uniformity of the determined thickness of the tube.

8. The method of claim 1, further comprising:
determining a plurality of element parameters for each of the plurality of tube elements of the tube; and
determining a plurality of tube parameters for the tube based on the plurality of element parameters.

9. A system for automatically identifying tube elements in a Boundary Representation (B-Rep)-based Computer Aided Design (CAD) model of a tube, the system comprising:
a processor; and
a memory communicatively coupled to the processor, wherein the memory stores processor-executable instructions, which, on execution, cause the processor to:
extract information corresponding to the B-Rep-based CAD model of the tube;
validate geometrical features of the B-Rep based CAD model of the tube based on the extracted information;
classify each of a plurality of faces of the tube into one of a set of face types, wherein the set of face types comprises a top face, a bottom face, or a lateral face, wherein the top face is located on outer surface of the tube, the bottom face is located on inner surface of the tube, and the lateral face is located on cross-section of the tube;
determine one or more regions on the tube using a set of connected top faces of the tube, wherein each of the one or more regions is a section of the tube with a consistent sweep path, and wherein each of the one or more regions is one of a length region, a bend region, or a spline region; and
generate a plurality of primary tube elements based on shapes of the plurality of regions, wherein each of the plurality of primary tube elements is one of a bend element, a length element, or a spline element.

10. The system of claim 9, wherein the processor-executable instructions further cause the processor to generate a set of secondary tube elements based on the plurality of primary tube elements.

11. The system of claim 10, wherein the plurality of primary tube elements and the set of secondary tube elements comprise a length element, a bend element, a spline element, and a collar element.

12. The system of claim 9, wherein extracting information further comprises identifying the plurality of faces from the B-Rep based CAD model of the tube.

13. The system of claim 9, wherein the processor-executable instructions further cause the processor to validate geometrical features of the B-Rep based CAD model by determining a tube type for the tube corresponding to the B-Rep based CAD model based on the extracted information, wherein the tube type is one of a hollow type, a solid type, or a mixed type, and wherein the tube type is determined by:
identifying one or more clue faces from the plurality of faces in the B-Rep-based CAD model; and
analysing the one or more clue faces of the B-Rep-based CAD model to determine the tube type.

14. The system of claim 13, wherein the processor-executable instructions further cause the processor to:
calculate a sweep path of the tube; and
validate consistency of circular cross-section of the tube.

15. The system of claim 13, wherein the processor-executable instructions further cause the processor to:
determine thickness of the tube based on the tube type using the extracted information; and
validate uniformity of the determined thickness of the tube.

16. The system of claim 9, wherein the processor-executable instructions further cause the processor to:
determine a plurality of element parameters for each of the plurality of tube elements of the tube; and
determine a plurality of tube parameters for the tube based on the plurality of element parameters.

17. A non-transitory computer-readable medium storing computer-executable instructions for automatically identifying tube elements in a Boundary Representation (B-Rep)-based Computer Aided Design (CAD) model of a tube, the computer-executable instructions configured for:
extracting information corresponding to the B-Rep-based CAD model of the tube;
validating geometrical features of the B-Rep based CAD model of the tube based on the extracted information;
classifying each of a plurality of faces of the tube into one of a set of face types, wherein the set of face types comprises a top face, a bottom face, or a lateral face, wherein the top face is located on outer surface of the tube, the bottom face is located on inner surface of the tube, and the lateral face is located on cross-section of the tube;
determining one or more regions on the tube using a set of connected top faces of the tube, wherein each of the one or more regions is a section of the tube with a consistent sweep path, and wherein each of the one or more regions is one of a length region, a bend region, or a spline region; and
generating a plurality of primary tube elements based on shapes of the plurality of regions, wherein each of the plurality of primary tube elements is one of a bend element, a length element, or a spline element.

18. The non-transitory computer-readable medium of the claim 17, wherein the computer-executable instructions further configured for generating a set of secondary tube elements based on the plurality of primary tube elements.

19. The non-transitory computer-readable medium of the claim 18, wherein the plurality of primary tube elements and the set of secondary tube elements comprise a length element, a bend element, a spline element, and a collar element.

20. The non-transitory computer-readable medium of the claim 15, wherein the computer-executable instructions further configured for identifying the plurality of faces from the B-Rep based CAD model of the tube.
